(19) United States
(12) Patent Application Publication
(10) Pub. No.: US 2017/0278778 A1
(43) Pub. Date: Sep. 28, 2017

(54) MICROELECTRONIC INTERCONNECT ADAPTOR

(71) Applicant: INTEL CORPORATION, Santa Clara, CA (US)

(72) Inventors: Christian Geissler, Teugn (DE); Klaus Reingruber, Langquaid (DE); Sven Albers, Regensburg (DE)

(73) Assignee: INTEL CORPORATION, Santa Clara, CA (US)

(21) Appl. No.: 15/622,552

(22) Filed: Jun. 14, 2017

Related U.S. Application Data
(62) Division of application No. 14/623,687, filed on Feb. 17, 2015.

(51) Int. Cl. H01L 23/498; H01L 21/48; H01L 23/13

(52) U.S. Cl. CPC H01L 23/49827; H01L 21/4853; H01L 23/49816; H01L 21/486; H01L 2924/15159; H01L 23/13; H01L 2924/15311

(57) ABSTRACT

An interconnect adaptor may be fabricated having a substantially planar surface, to which a microelectronic package may be electrically attached, and a non-planar surface with at least one interconnect extending from the interconnect adaptor planar surface to the interconnect adaptor non-planar surface. The interconnect adaptor non-planar surface may be shaped to substantially conform to a shape of a microelectronic substrate to which it may be attached, which eliminates the need to bend or otherwise adapt the microelectronic package to conform to the microelectronic substrate.

### RELATED APPLICATION

The present application is a divisional of U.S. patent application Ser. No. 14/623,687, filed on Feb. 17, 2015, entitled “MICROELECTRONIC INTERCONNECT ADAPTOR”, which is hereby incorporated herein in their entirety and for all purposes.

### TECHNICAL FIELD

Embodiments of the present description generally relate to the field of microelectronic devices, and, more particularly, to microelectronic structures which include an microelectronic interconnect adaptor that allows the microelectronic structures to be attached to a variety of substrates.

### BACKGROUND

As microelectronic devices are becoming ever smaller, the ability to fabricate microelectronic devices into wearable microelectronic systems is becoming prevalent. Wearable microelectronics systems are expected to be common products for medical applications and for enabling the Internet of Things (“IoT”—equipping multiple objects with small identification devices, which may connect with the internet to network and communicate with each other).

For packaging such wearable devices, there will need to be, on one hand, increased integration density (such as System in Package (SiP)) and, on the other hand, increased dimensional reduction (e.g. length (x), width (y), and height (z) dimensions). Reducing the length and width is important in order to reduce the surface area required on a printed circuit board or module to which the microelectronic packages are mounted. Reducing the height is important not only for dimensional reduction, but also for bending/flexibility to assemble the packages on flexible printed circuit boards or on slightly bent printed circuit boards. This bending/flexibility can be achieved by using thin microelectronic packages with very thin microelectronic dice inside. These thin microelectronic packages may be mounted on a flexible printed circuit board, which may then be slightly bent to fit into a module or chase. However, common microelectronic packages, such as Fan-Out Wafer Level Packages (FO WLP), Wafer Level Chip-Scale Packages (WLCSP), or Flip Chip (FC) packages, even if extremely thinned have only a very limited bending flexibility. Furthermore, extreme thinning of microelectronic packages and the microelectronic dice therein reduces the mechanical stability thereof. Moreover, bending of microelectronic dice (such as silicon-based dice) may have negative impact on performance due to asymmetric mechanical stress on crystal structure thereof. Depending on bending direction, performance of integrated circuitry, such as transistors, formed in the microelectronic dice may be reduced, for example, by as much as about 20%. This may lead to significant non-uniformities of the performance of integrated circuitry within the bent microelectronic dice, which may require re-designing the integrated circuitry therein.

Yet further, for highly bent printed circuit boards, such as tube shaped surfaces, stepped surfaces, 90° z-direction angles, or for bridging purposes, bending the microelectronic packages is not suitable. Although, some of these issues may be addressed with printed electronics technologies, these organic based devices suffer from poor electrical performance.

Therefore, there is a need for microelectronic package designs which do not require bending when used in wearable microelectronic systems.

### BRIEF DESCRIPTION OF THE DRAWINGS

The subject matter of the present disclosure is particularly pointed out and distinctly claimed in the concluding portion of the specification. The foregoing and other features of the present disclosure will become more fully apparent from the following description and appended claims, taken in conjunction with the accompanying drawings. It is understood that the accompanying drawings depict only several embodiments in accordance with the present disclosure and are, therefore, not to be considered limiting of its scope. The disclosure will be described with additional specificity and detail through use of the accompanying drawings, such that the advantages of the present disclosure can be more readily ascertained, in which:

FIG. 1 illustrates a cross-sectional view of a microelectronic package attached to an interconnect adaptor having a substantially planar surface and a non-planar surface with interconnects extending from the planar surface to the non-planar surface, according to an embodiment of the present description.

FIGS. 2-6 illustrate cross-sectional views of various configurations of interconnect adaptors attached to microelectronic substrates, according to embodiments of the present description.

FIGS. 7-16 illustrate cross-sectional views of a process of fabricating the microelectronic component of FIG. 1, according to one embodiment of the present description.

FIG. 17 is a flow diagram of a process of fabricating a microelectronic component, according to an embodiment of the present description.

FIG. 18 illustrates a computing device in accordance with one implementation of the present description.

### DESCRIPTION OF EMBODIMENTS

In the following detailed description, reference is made to the accompanying drawings that show, by way of illustration, specific embodiments in which the claimed subject matter may be practiced. These embodiments are described in sufficient detail to enable those skilled in the art to practice the subject matter. It is to be understood that the various embodiments, although different, are not necessarily mutually exclusive. For example, a particular feature, structure, or characteristic described herein, in connection with one embodiment, may be implemented within other embodiments without departing from the spirit and scope of the claimed subject matter. References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, it is to be understood that the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled. In the drawings, like numerals refer to the same or similar elements or functionality throughout the several views, and that elements depicted therein are not necessarily to scale with one another, rather individual elements may be enlarged or reduced in order to more easily comprehend the elements in the context of the present description.

The terms “over”, “to”, “between” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

Embodiments of the present description may include an interconnect adaptor having a substantially planar surface, to which a microelectronic package may be electrically attached, and a non-planar surface with at least one interconnect extending from the interconnect adaptor planar surface to the interconnect adaptor non-planar surface. The interconnect adaptor non-planar surface may be shaped to substantially conform to a shape of a microelectronic substrate to which it may be attached, which eliminates the need to bend or otherwise adapt the microelectronic package to conform to the microelectronic substrate.

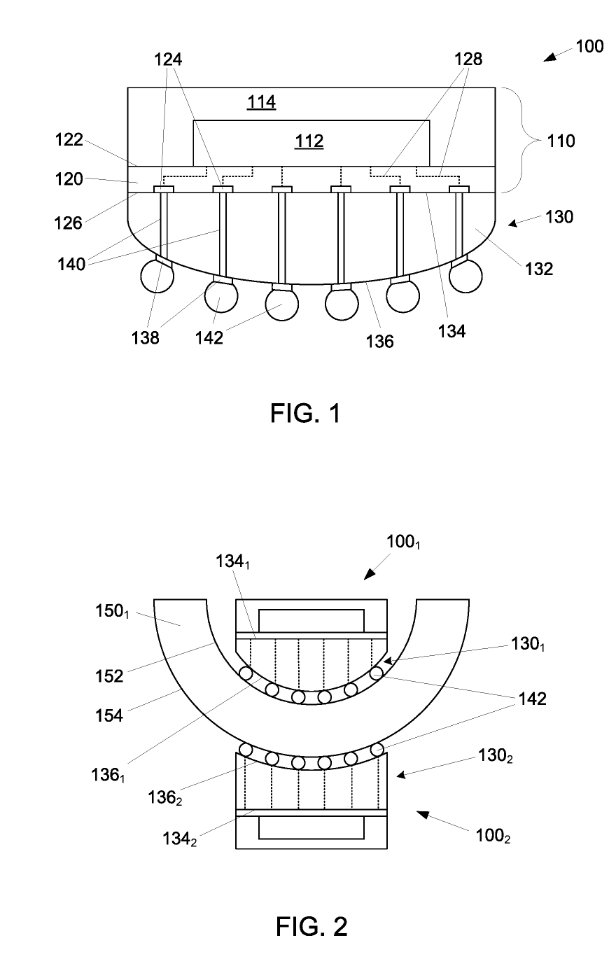

FIG. 1 illustrates a microelectronic component 100, according to one embodiment of the present invention. As shown in FIG. 1, a microelectronic package 110 may be attached to an interconnect adaptor 130. The interconnect adaptor 130 may comprise an interconnect adaptor body 132 have a substantially planar surface 134, to which the microelectronic package 110 is electrically attached, and a non-planar surface 136 with at least one electronically conductive interconnect 140 extending from the interconnect adaptor body planar surface 134 to the interconnect adaptor body non-planar surface 136.

As shown in FIG. 1, the microelectronic package 110 may comprise a microelectronic device 112, such as a microprocessor, a chipset, a graphics device, a wireless device, a memory device, an application specific integrated circuit, or the like, electrically attached to a first surface 122 of an interposer or a build-up layer 120. An encapsulant material 114 may encapsulate the microelectronic device 112 and abut a portion of the interposer/build-up layer first surface 122. The interposer/build-up layer 120 may be electrically attached to the interconnects 140 at the interconnect adaptor body planar surface 134 with corresponding, mirror-image microelectronic package bond pads 124 formed at a second surface 126 of the interposer/build-up layer 120. The microelectronic package bond pads 124 may be electrically connected to integrated circuitry (not shown) within the microelectronic device 112 through conductive routes (shown as dashed lines 128) extending through the interposer/build-up layer 120.

Since the microelectronic package 110 is mounted to the interconnect adaptor planar surface 134, the microelectronic package 110 will stay planar and there is no need bend or otherwise distort the microelectronic package 110. Thus, as will be understood to those skilled in the art, although the microelectronic package 110 is illustrated in FIG. 1 as a Fan-Out Wafer Level Package (FO WLP), any appropriate packaging technologies can be used, as will be discussed.

The interconnect adaptor 130 may have at least one bond pad 138 formed at the interconnect adaptor body non-planar surface 136, wherein each bond pad 138 is in electrical contact with a corresponding interconnect 140. A connector 142, illustrated in FIG. 1 as a solder ball, may be formed on each of the interconnect adaptor bond pads 138.

The interconnect adaptor body 132 may be any appropriate, substantially rigid, dielectric material. The interconnects 140, the interconnect adaptor bond pads 138, and the microelectronic package bond pads 124 may be formed from any appropriate conducting material, including but not limited to metals and metal alloys, such as copper, silver, gold, nickel, and alloys thereof. The encapsulant material 114 may be any appropriate encapsulation material, including but not limited to, silica-filled epoxies and resins. In one embodiment, the interposer/build-up layer 120 may be formed from multiple layers of dielectric material (not shown) including, but not limited to, silicon dioxide (SiO₂), silicon oxynitride (SiOₓN_{y}), and silicon nitride (Si₃N₄) and silicon carbide (SiC), liquid crystal polymer, epoxy resin, bismaleimide triazine resin, polyimide materials, and the like. The conductive routes 128 may be formed to extend between and through the dielectric material layers (not shown) and may be made of any appropriate conductive material, including, but not limited to, copper, silver, gold, nickel, and alloys thereof. The processes used for forming the microelectronic package 110 and components thereof are well known to those skilled in the art, and for the sake of brevity and conciseness will not be described or illustrated herein.

FIGS. 2-6 illustrate various embodiments of microelectronic components 100 electrically connected to various microelectronic substrates 150 by the connectors 142. The microelectronic substrates 150 may comprise any appropriate dielectric material, including, but not limited to, liquid crystal polymer, epoxy resin, bismaleimide triazine resin, FR4, polyimide materials, and the like, and may include conductive routes (not shown) formed therein and/or thereon to form any desired electrical route within the microelectronic substrate 150, between the microelectronic components 100, and/or with additional external components (not shown). The processes used for forming the microelectronic substrate 150 are well known to those skilled in the art, and for the sake of brevity and conciseness will not be described or illustrated herein. As illustrated in FIGS. 2-6, the microelectronic substrates 150 may have a variety of shapes, wherein the interconnect adaptors 130 are configured to adjust to the shape of the microelectronic substrates 150.

As shown in FIG. 2, the microelectronic components 1001,1002 may have interconnect adaptors 130₁, 130₂, respectively, which include interconnect adaptor body non-planar surfaces 136₁, 136₂, respectively, that are curved or arcuate. In the upper microelectronic component 1001, the interconnector adaptor body arcuate surface 1361 may be substantially convex relative to the interconnect adaptor body planar surface 134₁, such that it may be attached to an interior surface 152 of a tube-shaped or a sphere-shaped microelectronic substrate 150₁. In the lower microelectronic component 1002, the interconnect adaptor body arcuate surface 1362 may be substantially concave relative to the interconnect adaptor body planar surface 1342, such that it may be attached to an exterior surface 154 of a tube-shaped or a sphere-shaped microelectronic substrate 1501.

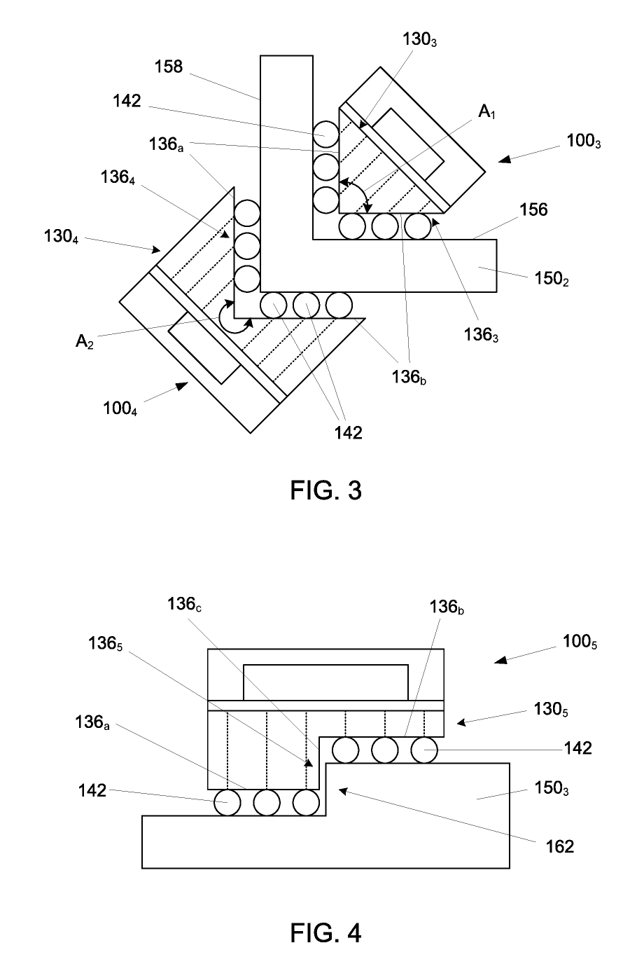

As shown in FIG. 3, both microelectronic components 100₃, 100₄ may have interconnect adaptors 130₃, 130₄, respectively, which include interconnect adaptor body non-planar surfaces 136₃, 136₄, respectively, that comprise two converging planar surfaces 136ₐ and 136_{b}. In the upper microelectronic component 1003, the converging planar surfaces 136ₐ and 136_{b} may be angled at an acute angle A₁ to one another, such that they may be attached to an interior surface 156 of a substantially L-shaped microelectronic substrate 1502. In the lower microelectronic component 1004, the converging planar surfaces 136ₐ and 136_{b} may be angled at an obtuse angle A₂ to one another, such that they may be attached to an exterior surface 158 of the substantially L-shaped microelectronic substrate 1502.

As shown in FIG. 4, the microelectronic component 1005 may have an interconnect adaptor 1305 which includes the interconnect adaptor body non-planar surfaces 1365 that comprises two planar surfaces 136ₐ and 136_{b} that are parallel non-planar to one another (e.g. on differing parallel planes) and a connecting surface 136 between two planar surfaces 136ₐ and 136_{b}. Such a configuration may allow for the electrical attachment of microelectronic component 100₅ to the microelectronic substrate 150₃, which has a stepped surface 162 substantially mirroring the interconnect adaptor body non-planar surface 136₅. As shown in FIG. 5, the microelectronic substrate 1504 need not have a stepped surface 162 (see FIG. 4) for the non-planar surface 1365 shown in FIG. 4 to be used. Rather, an active surface 172 of a secondary microelectronic device 170, either active or passive, may be electrically attached to a planar microelectronic substrate 1504, wherein one planar surface 136ₐ of the interconnect adaptor 130₅ is electrically connected to the microelectronic substrate 1504 and the other planar surface 136_{b} of the interconnect adaptor 130₅ is electrically connected to a back surface 174 of the secondary microelectronic device 170, such as with through-silicon vias (not shown).

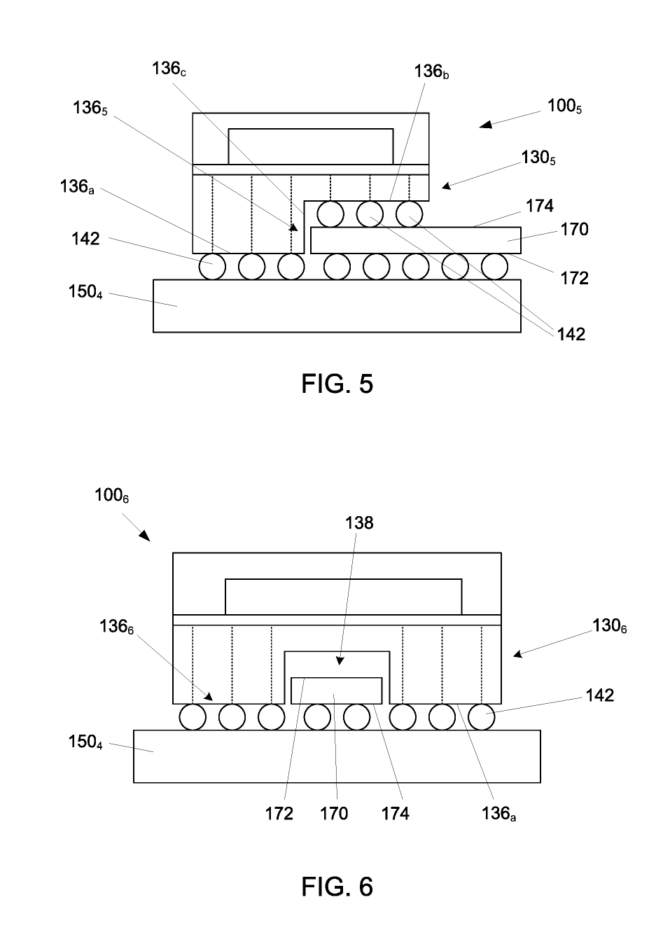

As shown in FIG. 6, the microelectronic component 100₆ may have an interconnect adaptor 1306 which includes the interconnect adaptor body non-planar surface 1366 that comprises at least one planar surface 136ₐ and a recess 138 extending into the interconnect adaptor 1306, such that the recess 138 can span over the secondary microelectronic device 170.

As it can be seen in FIGS. 2-6, the embodiments of the present description may allow for the microelectronic component 100 to be attached to bent or non-planar substrates 150 without the need to bend/stress the microelectronic package 110 and microelectronic device 112 therein. The microelectronic component 100 may allow for attachment to the microelectronic substrate 150 in positions where currently no placement is possible, which may reduce the form factor (e.g. size) of the resulting system or module as a whole and allow for attachment inside of small tubes or wearable items like rings or bracelets. Further, the embodiment of the present description may not require any microelectronic package or microelectronic die thinning, which might lead to performance degradation due to mechanical stress, as will be understood to those skilled in the art. Thus, standard, high performance packaging technologies like Fan-Out Wafer Level Packages (FO WLP) (illustrated in FIGS. 1-6), Wafer Level Chip-Scale Packages (WLCSP), Flip Chip (FC) packages, Quad Flat No-leads (QFN) packages, Dual Flat No-leads (DFN) packages, and the like, having many features, such as System in Package (SiP), Package-on-Package (PoP), 3D-stacking, and the like, may be used.

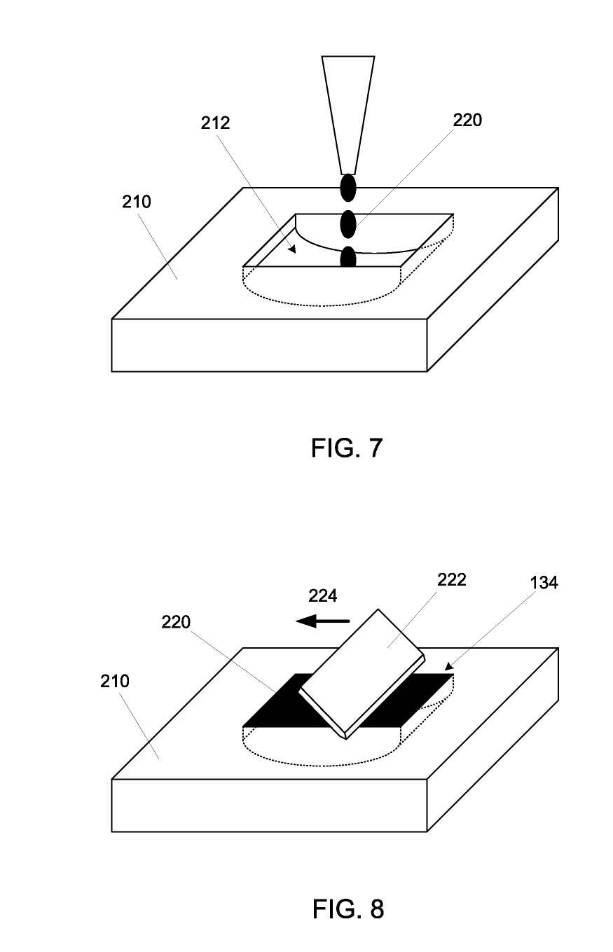

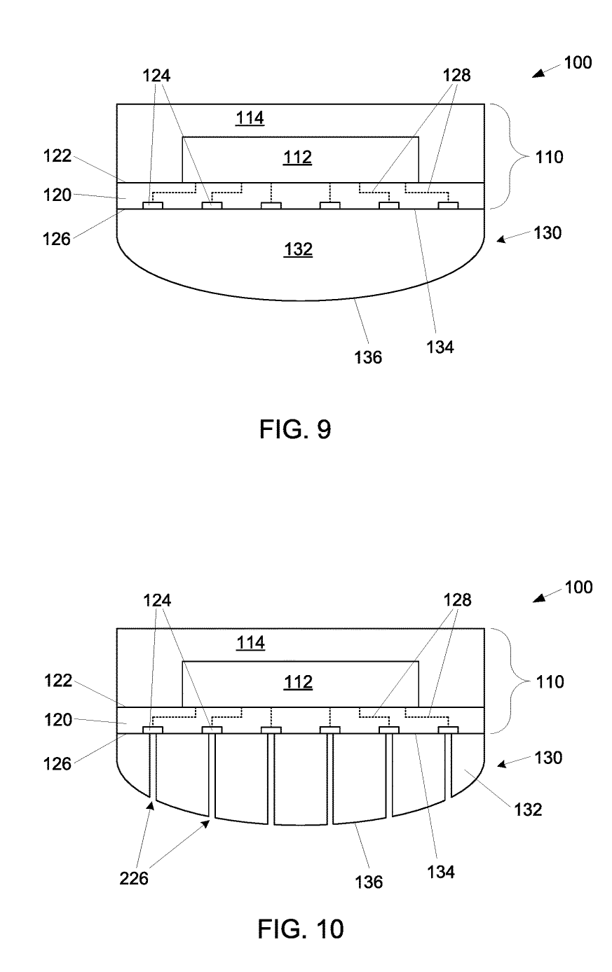

FIGS. 7-16 illustrate one embodiment of fabricating the microelectronic component 100 illustrated in FIG. 1. As shown in FIG. 7, a mold chase 210 may be formed having at least one recess 212 therein. As will be understood to those skilled in the art, the mold chase recess 212 may have a negative of the desired shape of the interconnect adaptor non-planar surface 136 (see FIG. 1). It is further understood by those skilled in the art that the configuration and number of mold chase recesses 212 may be determined by a package body technology used, such as panel, wafer, strip form, and the like. As further shown in FIG. 7, a liquid dielectric mold compound 220 may be deposited in and fill the mold chase recess 212. Once filled, excess dielectric mold compound 220 may be removed, such as by a removal tool or squeegee 222 drawn across (arrow 224) the mold case 210, to form the interconnect adaptor planar surface 134, as shown in FIG. 8. As shown in FIG. 9, the dielectric mold compound 220 (see FIG. 8) may be cured or partially cured to form the interconnector adaptor body 132 of the interconnect adaptor 130 and the microelectronic package 110 may be attached to the interconnect adaptor body planar surface 134, which may occur before or after the removal of the dielectric mold compound 220 from the mold chase 210 (see FIGS. 7 and 8). Although a molding process is illustrated in FIGS. 7 and 8, it is understood that a bulk dielectric material could be mechanically polished, laser ablated, or the like to form the interconnector adaptor body 132, or the inter connector adaptor body 132 could be fabricated in 3-D printing process or the like.

After the formation of the interconnector adaptor body 132, as shown in FIG. 10, at least one via 226 may be formed to extend from the interconnect adaptor body non-planar surface 136 to the interconnect adaptor body planar surface 134, wherein a portion of each microelectronic package bond pad 124 may be exposed. In one embodiment, the vias 226 may be formed by laser drilling. The use of laser drilling may result in no or very low taper to the vias 226 and may result in the vias 226 having diameters of between about 20 μm and 25 μm, which is independent of a distance between the interconnect adaptor body non-planar surface 136 to the interconnect adaptor body planar surface 134. If an electroless plating process is to be used to form the interconnects 140 (see FIG. 1), a seed layer (not shown) may be formed, such as by sputter deposition or electroless plating, on the exposed portions of each microelectronic package bond pad 124, the sidewalls of the vias 226, and the interconnect adaptor body non-planar surface 136.

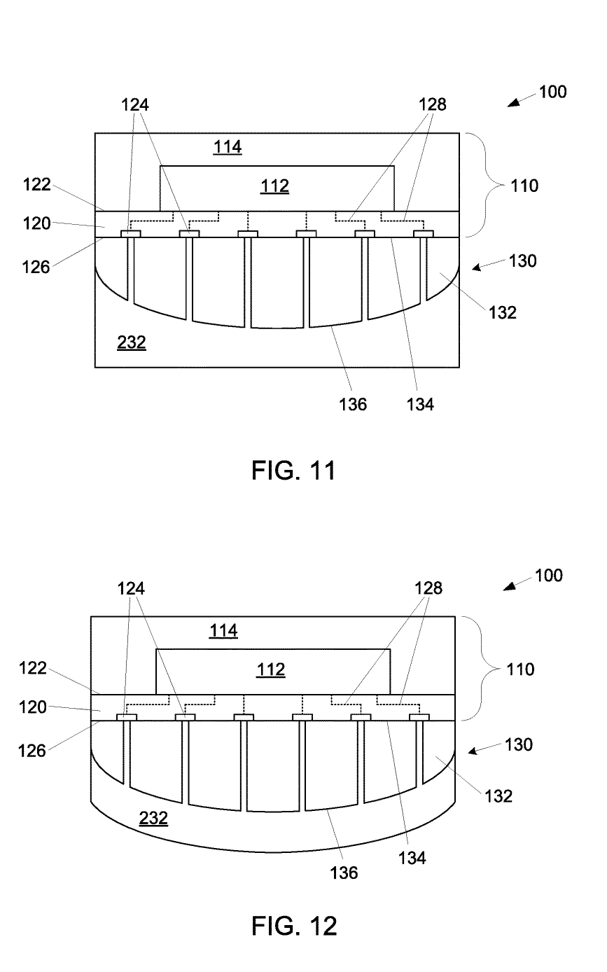

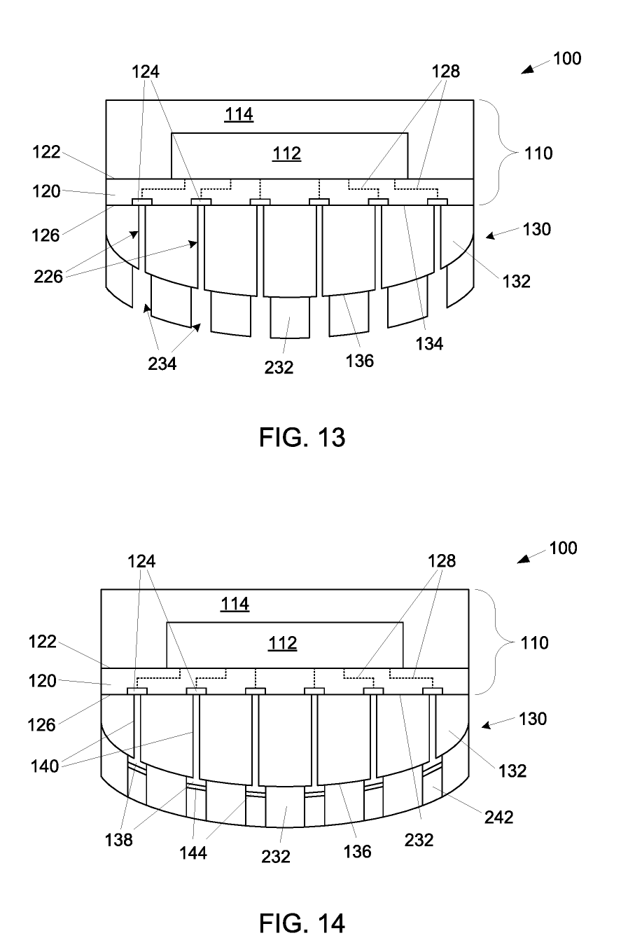

After forming the vias 226 (see FIG. 10), a resist material layer 232 may be formed over the interconnect adaptor body non-planar surface 136 either non-conformally, such as by spin-on coating, as shown in FIG. 11, or conformally, such as by spray coating, as shown in FIG. 12. In one embodiment, the resist thickness may be between about 50 μm and 100 μm. As shown in FIG. 13, openings 234 may be formed through the resist material layer 232 to the vias 226 and the material within the vias 226 may be removed, such as by photolithography and/or laser drilling. In one embodiment, a negative tone resist material layer 232 may be used to enable removal from the vias 226.

As shown in FIG. 14, the interconnects 140 may be formed within the vias 226 (see FIG. 13). In one embodiment, the interconnects 140 may be formed by filling the vias 226 (see FIG. 13) with an electroless plating process (a seed layer (not shown) would be deposited after formation of the vias 226, as discussed with regard to FIG. 10). As shown in FIG. 14, the plating process may result in the formation of the interconnect adaptor bond pads 138 which are integral with their respective interconnect 140. In one embodiment, the interconnects 140 may be formed from any appropriate metal. In a specific embodiment, the interconnects 140 may be formed from copper. In another embodiment, for vias 226 (see FIG. 13) having diameters of between about 20 μm and 25 μm, the thickness of the plated material should be between about 15 μm and 20 μm to fill the vias 226 (see FIG. 13). As further shown in FIG. 14, after the formation of the interconnects 140 and interconnect adaptor bond pads 138, an underbump metallization structure 144, such a nickel barrier layer and a tin/silver wetting layer, may be formed on each interconnect adaptor bond pad 138. As still further shown in FIG. 14, a solder material 242 may be deposited on each underbump metallization structure 144. The solder material 242 may be any appropriate material, including, but not limited to, lead/tin alloys, such as 63% tin/37% lead solder, and high tin content alloys (e.g. 90% or more tin), such as tin/bismuth, eutectic tin/silver, ternary tin/silver/copper, eutectic tin/copper, and similar alloys.

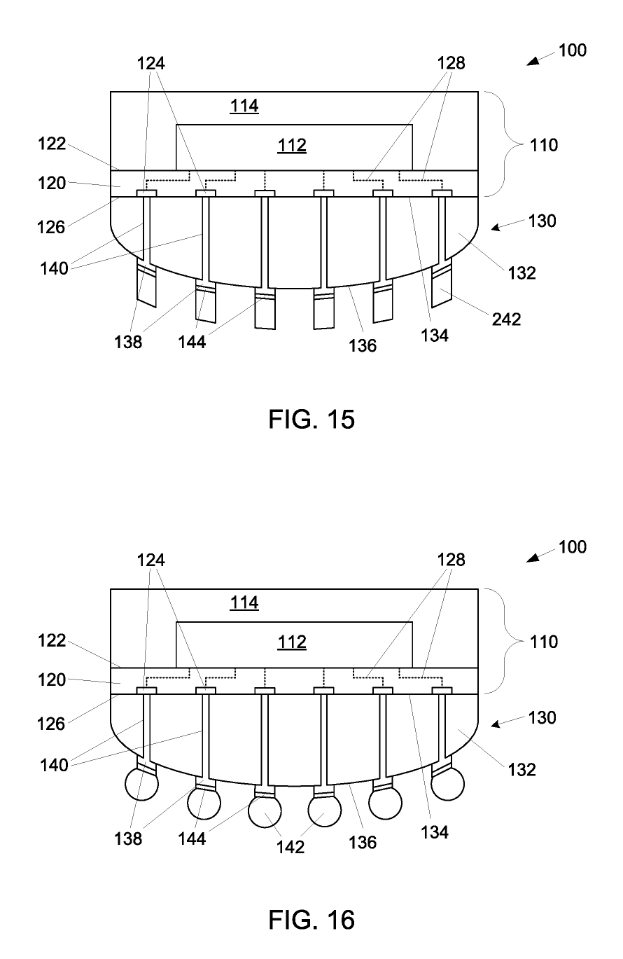

As shown in FIG. 15, the resist material layer 232 (see FIG. 14) may be removed as well as any remaining seed layer material (not shown). As shown in FIG. 16, the solder material 242 (see FIG. 15) may be reflowed (heated) to from the connectors 142 (e.g. solder balls) and the resulting microelectronic component 100. It is understood that if a plurality of microelectronic components 100 were formed simultaneously and integrally, they would be singulated, such as by mechanical dicing, after the formation of the connectors 142.

It is understood that a similar process approach may be used to form differently shaped interconnect adaptor body non-planar surfaces 136, and it is further understood that process adaptations might be necessary.

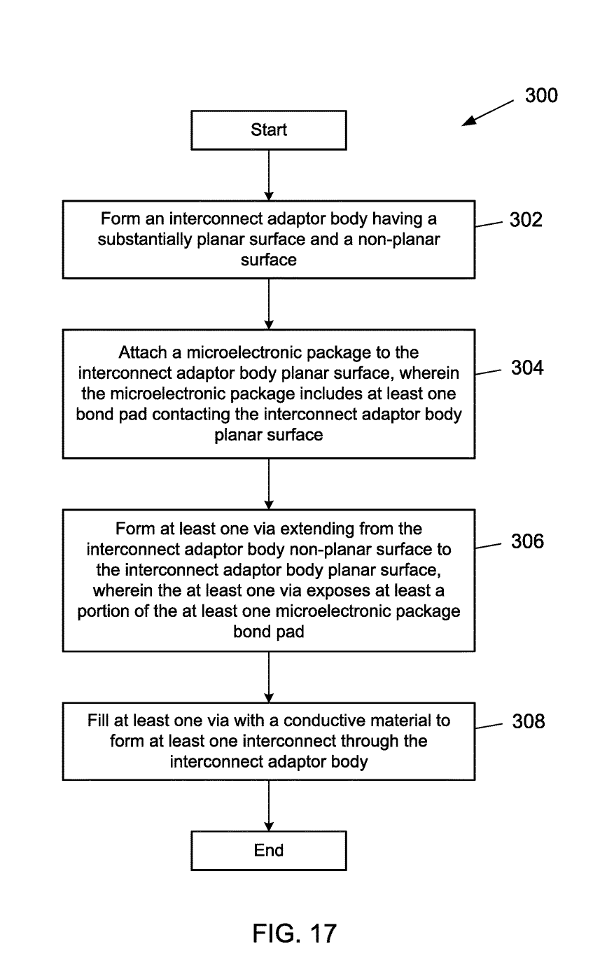

FIG. 17 is a flow chart of a process 300 of fabricating a flexible microelectronic system according to an embodiment of the present description. As set forth in block 302, an interconnect adaptor body having a substantially planar surface and a non-planar surface may be formed. A microelectronic package may be attached to the interconnect adaptor body planar surface, wherein the microelectronic package includes at least one bond pad contacting the interconnect adaptor body planar surface, as set forth in block 304. As set forth in block 306, at least one via may be formed extending from the interconnect adaptor body non-planar surface to the interconnect adaptor body planar surface, wherein the at least one via exposes at least a portion of at least one microelectronic package bond pad. At least one via may be filled with a conductive material to form at least one interconnect through the interconnect adaptor body, as set forth in block 308.

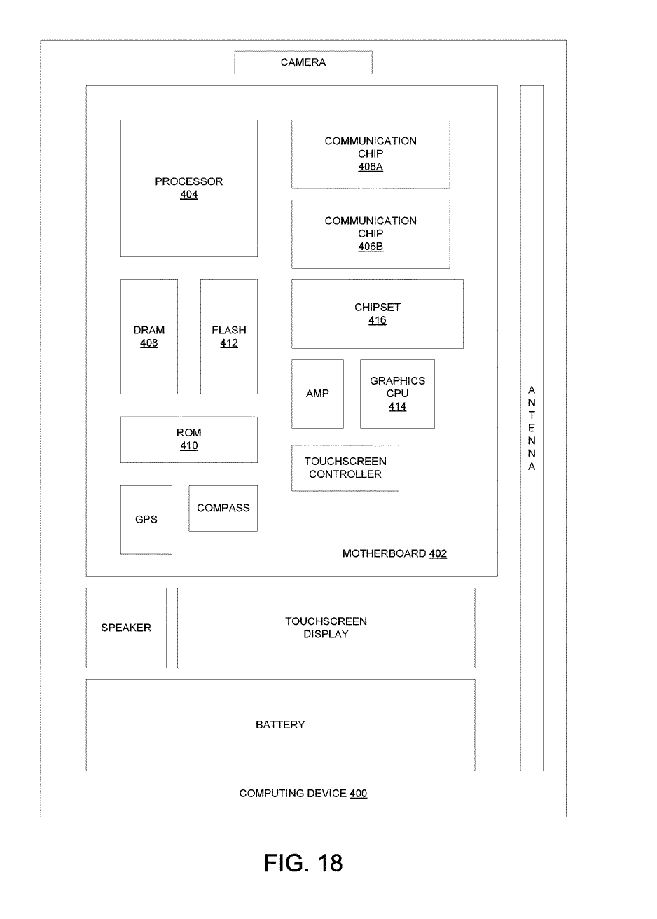

FIG. 18 illustrates a computing device 400 in accordance with one implementation of the present description. The computing device 400 houses a board 402. The board may include a number of microelectronic components, including but not limited to a processor 404, at least one communication chip 406A, 406B, volatile memory 408, (e.g., DRAM), non-volatile memory 410 (e.g., ROM), flash memory 412, a graphics processor or CPU 414, a digital signal processor (not shown), a crypto processor (not shown), a chipset 416, an antenna, a display (touchscreen display), a touchscreen controller, a battery, an audio codec (not shown), a video codec (not shown), a power amplifier (AMP), a global positioning system (GPS) device, a compass, an accelerometer (not shown), a gyroscope (not shown), a speaker (not shown), a camera, and a mass storage device (not shown) (such as hard disk drive, compact disk (CD), digital versatile disk (DVD), and so forth). Any of the microelectronic components may be physically and electrically coupled to the board 402. In some implementations, at least one of the microelectronic components may be a part of the processor 404.

The communication chip enables wireless communications for the transfer of data to and from the computing device. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device may include a plurality of communication chips. For instance, a first communication chip may be dedicated to shorter range wireless communications such as Wi-Fi and Bluetooth and a second communication chip may be dedicated to longer range wireless communications such as GPS, EDGE, GPRS, CDMA, WiMAX, LTE, Ev-DO, and others.

The term “processor” may refer to any device or portion of a device that processes electronic data from registers and/or memory to transform that electronic data into other electronic data that may be stored in registers and/or memory.

Any of the microelectronic components within the computing device 400 may include a microelectronic structure having an interconnect adaptor as described above.

In various implementations, the computing device may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device may be any other electronic device that processes data.

It is understood that the subject matter of the present description is not necessarily limited to specific applications illustrated in FIGS. 1-18. The subject matter may be applied to other microelectronic devices and assembly applications, as well as any appropriate electronic application, as will be understood to those skilled in the art.

The following examples pertain to further embodiments. Specifics in the examples may be used anywhere in one or more embodiments.

In Example 1, a microelectronic component may comprise an interconnect adaptor having a substantially planar surface and a non-planar surface with at least one electrically conductive interconnect extending from the planar surface to the non-planar surface.

In Example 2, the subject matter of Example 1 can optionally include the non-planar surface comprising an arcuate surface.

In Example 3, the subject matter of Example 2 can optionally include the arcuate non-planar surface being concave relative to the planar surface.

In Example 4, the subject matter of Example 2 can optionally include the arcuate non-planar surface being convex relative to the planar surface.

In Example 5, the subject matter of Example 1 can optionally include the non-planar surface comprising at least two planar surfaces.

In Example 6, the subject matter of Example 5 can optionally include the at least two planar surfaces forming an acute angle therebetween.

In Example 7, the subject matter of Example 5 can optionally include the at least two planar surfaces forming an obtuse angle therebetween.

In Example 8, the subject matter of Example 5 can optionally include the at least two planar surfaces being in a parallel non-planar configuration to one another.

In Example 9, the subject matter of Example 1 can optionally include a microelectronic package attached to the interconnect adaptor planar surface.

In Example 10, a method of fabricating a microelectronic structure may comprise forming an interconnect adaptor body having a substantially planar surface and a non-planar surface; attaching a microelectronic package to the interconnect adaptor body planar surface, wherein the microelectronic package includes at least one bond pad contacting the interconnect adaptor body planar surface; forming at least one via extending from the interconnect adaptor body non-planar surface to the interconnect adaptor body planar body, wherein the at least one via exposes at least a portion of at least one microelectronic package bond pad; and filling the at least one via with a conductive material to form at least one interconnect through the interconnect adaptor body.

In Example 11, the subject matter of Example 10 can optionally include forming an interconnect adaptor body comprising molding an interconnect adaptor body.

In Example 12, the subject matter of Example 10 can optionally include forming the at least one via comprising laser drilling at least one via extending from the interconnect adaptor body non-planar surface to the interconnect adaptor body planar body.

In Example 13, the subject matter of Example 10 can optionally include filling the at least one via with a conductive material comprising plating a metal in the at least one via to form at least one interconnect through the interconnect adaptor body.

In Example 14, the subject matter of Example 13 can optionally include plating a metal in the at least one via comprising plating copper in the at least one via.

In Example 15, the subject matter of any of Examples 10 to 14 can optionally include forming the interconnect adaptor body comprising forming the interconnect adaptor body having a substantially planar surface and a non-planar surface, wherein the non-planar surface comprises an arcuate surface.

In Example 16, the subject matter of Example 15 can optionally include the arcuate non-planar surface being concave relative to the planar surface.

In Example 17, the subject matter of Example 15 can optionally include the arcuate non-planar surface being convex relative to the planar surface.

In Example 18, the subject matter of any of Examples 10 to 14 can optionally include forming the interconnect adaptor body comprising forming the interconnect adaptor body having a substantially planar surface and a non-planar surface, wherein the non-planar surface comprises at least two planar surfaces.

In Example 19, the subject matter of Example 18 can optionally include the at least two planar surfaces forming an acute angle therebetween.

In Example 20, the subject matter of Example 18 can optionally include the at least two planar surfaces forming an obtuse angle therebetween.

In Example 21, the subject matter of Example 18 can optionally include the at least two planar surfaces are in a parallel non-planar configuration to one another.

In Example 22, an electronic system may comprise a board; and a microelectronic component including: an interconnect adaptor having a substantially planar surface and a non-planar surface with at least one electrically conductive interconnect extending from the planar surface to the non-planar surface; and a microelectronic package attached to the interconnect adaptor planar surface; wherein the microelectronic component is electrically attached to the board by connectors extending from the interconnect adaptor non-planar surface.

In Example 23, the subject matter of Example 22 can optionally include the non-planar surface comprising an arcuate surface.

In Example 24, the subject matter of Example 23 can optionally include the arcuate non-planar surface being concave relative to the planar surface.

In Example 25, the subject matter of Example 23 can optionally include the arcuate non-planar surface being convex relative to the planar surface.

In Example 26, the subject matter of Example 22 can optionally include the non-planar surface comprising at least two planar surfaces.

In Example 27, the subject matter of Example 26 can optionally include the at least two planar surfaces forming an acute angle therebetween.

In Example 28, the subject matter of Example 26 can optionally include the at least two planar surfaces forming an obtuse angle therebetween.

In Example 29, the subject matter of Example 26 can optionally include the at least two planar surfaces being in a parallel non-planar configuration to one another.

Having thus described in detail embodiments of the present description, it is understood that the present description defined by the appended claims is not to be limited by particular details set forth in the above description, as many apparent variations thereof are possible without departing from the spirit or scope thereof

What is claimed is:

1. A microelectronic component comprising an interconnect adaptor having a substantially planar surface and a non-planar surface with at least one electrically conductive interconnect extending from the planar surface to the non-planar surface, wherein the non-planar surface comprises at least two planar surfaces.

2. The microelectronic component of claim 1, wherein the at least two planar surfaces form an acute angle therebetween.

3. The microelectronic component of claim 1, wherein the at least two planar surfaces form an obtuse angle therebetween.

4. The microelectronic component of claim 1, wherein the at least two planar surfaces are in a parallel non-planar configuration to one another.

5. The microelectronic component of claim 1, further including a microelectronic package attached to the interconnect adaptor planar surface.

6. A method of fabricating a microelectronic structure comprising:
forming an interconnect adaptor body having a substantially planar surface and a non-planar surface, wherein the non-planar surface comprises at least two planar surfaces;
attaching a microelectronic package to the interconnect adaptor body planar surface, wherein the microelectronic package includes at least one bond pad contacting the interconnect adaptor body planar surface;
forming at least one via extending from the interconnect adaptor body non-planar surface to the interconnect adaptor body planar surface, wherein the at least one via exposes at least a portion of at least one microelectronic package bond pad; and
filling the at least one via with a conductive material to form at least one interconnect through the interconnect adaptor body.

7. The method of claim 6, wherein forming an interconnect adaptor body comprises molding an interconnect adaptor body.

8. The method of claim 6, wherein forming the at least one via comprises laser drilling at least one via extending from the interconnect adaptor body non-planar surface to the interconnect adaptor body planar body.

9. The method of claim 6, wherein filling the at least one via with a conductive material comprising plating a metal in the at least one via to form at least one interconnect through the interconnect adaptor body.

10. The method of claim 9, wherein plating a metal in the at least one via comprising plating copper in the at least one via.

11. The method of claim 6, wherein the at least two planar surfaces form an acute angle therebetween.

12. The method of claim 6, wherein the at least two planar surfaces form an obtuse angle therebetween.

13. The method of claim 6, wherein the at least two planar surfaces are in a parallel non-planar configuration to one another.

14. An electronic system, comprising:
a board; and
a microelectronic component including:
an interconnect adaptor having a substantially planar surface and a non-planar surface with at least one electrically conductive interconnect extending from the planar surface to the non-planar surface, wherein the non-planar surface comprises at least two planar surfaces; and
a microelectronic package attached to the interconnect adaptor planar surface;
wherein the microelectronic component is electrically attached to the board by connectors extending from the interconnect adaptor non-planar surface.

15. The electronic system of claim 14, wherein the at least two planar surfaces form an acute angle therebetween.

16. The electronic system of claim 14, wherein the at least two planar surfaces form an obtuse angle therebetween.

17. The electronic system of claim 14, wherein the at least two planar surfaces are in a parallel non-planar configuration to one another.

18. The electronic system of claim 14, further including a microelectronic package attached to the interconnect adaptor planar surface.
